(19) United States
(12) Patent Application Publication
(10) Pub. No.: US 2021/0365600 A1
(43) Pub. Date: Nov. 25, 2021

(54) STRUCTURAL ANALYTICAL MODEL APPARATUS AND METHOD

(71) Applicant: GRAPHISOFT SE, Budapest (HU)

(72) Inventors: Ákos Kolos Rechtorisz, Budapest (HU); Gergely Zupán, Budapest (HU); Gyula Rasztovich, Budapest (HU)

(73) Assignee: GRAPHISOFT SE, Budapest (HU)

(21) Appl. No.: 16/881,828

(22) Filed: May 22, 2020

(51) Int. Cl. G06F 30/13; G06T 17/10

(52) U.S. Cl. CPC G06F 30/13; G06T 17/10

(57) ABSTRACT

A data processing system, comprising an architectural building model conversion apparatus operating on a first processor and implementing one or more algorithms that cause the processor to receive an architectural building model and to generate a structural engineering model and a plurality of user control interfaces, each operating on one of a plurality of second processors and implementing one or more algorithms that allow a user to control conversion of one or more architectural model elements to one or more corresponding structural engineering model elements.

### TECHNICAL FIELD

The present disclosure relates generally to computer-implemented processes for building design, and more particularly to an active building information modeling apparatus operating on a processor and which automatically converts architectural building elements into structural engineering elements.

### BACKGROUND OF THE INVENTION

During the building design process, multiple users, such as architects and structural engineers, use computer-assisted three dimensional building model apparatuses, which may be referred to as Building Information Modeling (BIM) apparatuses. BIM apparatus users can create a building model that has a high level of construction detail. However, architects and structural engineers require different levels of building details, as well as different view setups of the exact same three-dimensional building model, and it is necessary to create different models for different applications.

### SUMMARY OF THE INVENTION

A data processing system is disclosed that includes an architectural building model conversion apparatus operating on a first processor that implements one or more algorithms, where the algorithms cause the processor to receive an architectural building model and to generate a structural engineering model. A plurality of user control interfaces are provided, each operating on one of a plurality of second processors. Each user control interface implements one or more algorithms that allow a user to control conversion of one or more architectural model elements to one or more corresponding structural engineering model elements, such as to guide the automated conversion process.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Aspects of the disclosure can be better understood with reference to the following drawings. The components in the drawings may be to scale, but emphasis is placed upon clearly illustrating the principles of the present disclosure. Moreover, in the drawings, like reference numerals designate corresponding parts throughout the several views, and in which:

FIG. 1 is a diagram of a system for providing a structural analytical model apparatus, in accordance with an example embodiment of the present disclosure;

FIG. 2 is a diagram of a system for providing adjustments to a structural analytical model, in accordance with an example embodiment of the present disclosure;

FIG. 3 is a diagram of an algorithm for providing a structural analytical model apparatus, in accordance with an example embodiment of the present disclosure; and

FIG. 4 is a diagram of an algorithm for providing adjustments to a structural analytical model, in accordance with an example embodiment of the present disclosure.

### DETAILED DESCRIPTION OF THE INVENTION

In the description that follows, like parts are marked throughout the specification and drawings with the same reference numerals. The drawing figures may be to scale and certain components can be shown in generalized or schematic form and identified by commercial designations in the interest of clarity and conciseness.

The present disclosure provides an analytical model generation processor that includes one or more algorithms that are configured to identify engineering technical requirements for BIM model elements, such as the element's core, and to automatically create a graphical representation for element engineering technical requirements that maintains the metadata for each element. The analytical model generation processor is configured to use and generate architectural views and engineering views of the BIM model elements, and to allow the views to coexist in the same building information modeling apparatus, such as to automatically synchronize and update one view when changes are made to a different view.

In an architectural building information modeling apparatus, elements can be described as columns, beams, walls, slabs, roofs and other suitable items. For a structural engineering requirement, the elements can be simplified to two types of elements, such as one-dimensional elements and two-dimensional elements. One-dimensional elements are those which can be geometrically described using only one axis, such as a beam or column, and can be represented according to a structural engineering view as a straight line between two points. In the same manner, two-dimensional elements can be geometrically described as a plane extended along two perpendicular axes, containing corner points (also called nodes), with lines connecting those points (edges) and the surface delimited by these edges.

In one example embodiment of the architectural building model apparatus, the plurality of elements can be classified as non-load bearing or load bearing elements. Elements that are classified as load bearing can be configured to coexist in the architectural three dimensional model and the structural engineering three dimensional model, or other suitable elements can also or alternatively provide that or other functions.

After the three dimensional architectural building model has been completed, an analytical model generation processor can utilize one or more algorithms to evaluate which elements are classified as load bearing, and from this plurality of elements, can identify which ones can be represented as one-dimensional elements or two-dimensional elements. Sequentially, the analytical model generation processor can utilize one or more algorithms to generate one or more queries for one or more of the selected elements to obtain their associated construction details for a structural engineering model or other suitable purposes. For example, the algorithm can identify if the elements are formed by a single material structure such as concrete or steel, if the elements are formed by a composite material structure, such as a wall element composed by concrete and an internal cover of gypsum board and painting, or other suitable information. The algorithm operating on the analytical model generation processor can then identify what the core material element is, can simultaneously determine its center of mass, and can generate other suitable data. For one-dimensional elements, the analytical model generation processor can identify the element and then place a graphical element in each end of the three dimensional building element (node) and a graphical element connecting those (line). For two-dimensional elements, the analytical model generation processor can identify the two vectors along which a plane is defined and the points through which the plane is delimited, and can then place graphical elements in those points (nodes), graphical elements connecting the two vectors (edge lines), and a graphical element delimited by all the previously described components (surface plane). The analytical model generation processor operations can be performed in the background of the building model apparatus user interface, without need of user intervention.

As a structural engineering technical requirement, the three dimensional structural model can implement the criteria of full continuity, where the elements are connected to nodes, adjacent surfaces have a partial or full common edge, and other suitable continuity properties. If such continuity is not fully achieved, a rule-based adjustment algorithm can be implemented through a dedicated user interface control or in other suitable manners to provide user-directed element-based adjustments. The continuity compliant adjustments can be used to provide modifications to the plurality of one-dimensional and two-dimensional elements, without having effect or altering the physical definition of the architectural three-dimensional building model elements.

In one example embodiment, the rule-based adjustment algorithm can be equipped with adjuster controls, such as a cut back control, a stretch control, an offset control, a snap control or other suitable controls. For each of the adjuster controls, a corresponding user interface control can be generated to allow a user to identify one or more target members, such as one-dimensional elements or two-dimensional elements that the adjustment should be applied against, one or more modified members, such as the one-dimensional elements or two-dimensional elements that can be adjusted, and other suitable parameters. For example, a graphical user interface control can be used to allow the user to select the different elements that the adjustment can be applied against and the different elements that can be adjusted, and to indicate the elements graphically, such as by different colors or effects. In addition to these user controls, the adjuster types can include additional controls for selecting user-defined parameters such as maximum allowed length to cut back and/or stretch, offset normal vector and/or element-based parameter (e.g. offset to thickest or thinnest core element), undo controls, history controls and other suitable controls to allow the user to easily implement changes and to reverse or modify the changes.

To verify and validate the continuity requirement, the present disclosure can include a three-dimensional building model verification algorithm operating on the processor that can provide a comprehensive report containing detailed information about which elements do not fulfill predetermined technical requirements. In case of any existing errors detected by the three-dimensional building model verification algorithm, the user can modify and/or complement the rule-based adjustment algorithm.

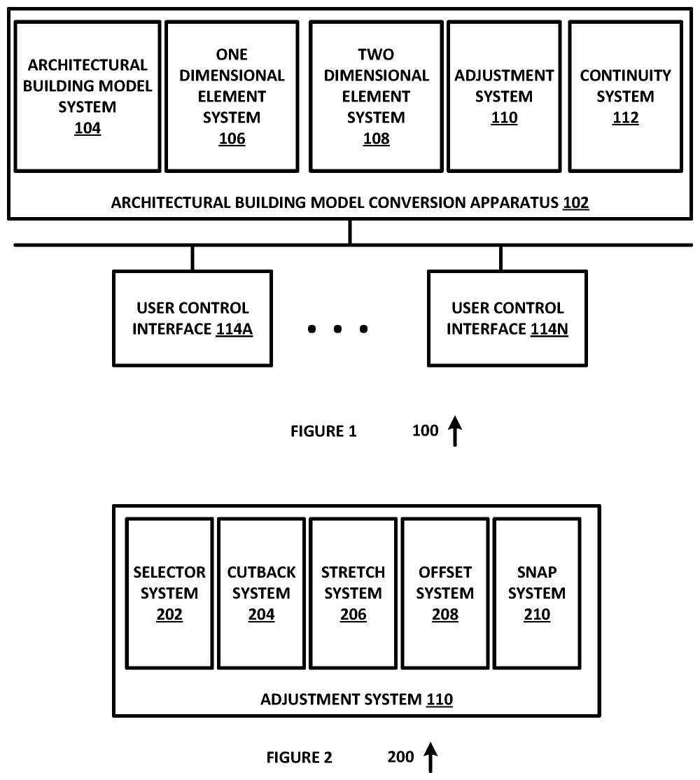

FIG. 1 is a diagram of a system 100 for providing a structural analytical model apparatus, in accordance with an example embodiment of the present disclosure. System 100 includes architectural building model conversion apparatus 102 and architectural building model system 104, one dimensional element system 106, two dimensional element system 108, adjustment system 110, continuity system 112 and user control interfaces 114A through 114N, each of which can be implemented in hardware or a suitable combination of hardware and software.

Architectural building model conversion apparatus 102 can be implemented as one or more algorithms operating on a processor that cause the processor to create a building model that includes a plurality of design elements with predetermined parameters, such as one or more architectural design element parameters that identify a location, color, style, texture and other aspects of the way a building should look. The algorithms operating as part of architectural building model conversion apparatus 102 are further configured to generate structural parameters as a function of the architectural parameters and engineering technical requirements, such as a maximum permissible load that may be placed on an element, a spacing requirement that constrains how close elements may be placed to each other, material compatibilities, construction requirements and so forth.

Architectural building model system 104 can be implemented as one or more algorithms operating on a processor that cause the processor to create a building information model, such as by allowing a user to select one or more architectural design elements and to assemble the architectural design elements into the building information model. In one example embodiment, the elements of architectural building model system 104 can have a first set of parameters that facilitate the architectural design of a building but which do not require determination of engineering technical requirements, which are typically determined after the architectural design phase.

One dimensional element system 106 can be implemented as one or more algorithms operating on a processor that cause the processor to identify one dimensional elements in the architectural model and to generate additional engineering design parameters that are associated with a single axis. In one example embodiment, a beam and a column can each be represented by structural engineering parameters that associated with a straight line between two points, such as material types, fabrication parameters, construction parameters, load parameters and so forth.

Two dimensional element system 108 can be implemented as one or more algorithms operating on a processor that cause the processor to identify two dimensional elements in the architectural model and to generate additional engineering parameters that are associated with a plane extended along two perpendicular axes, containing corner points (also called nodes), lines connecting those points (edges) and a surface delimited by the edges, and to generate additional engineering design parameters that are associated with the plane. In one example embodiment, a wall can each be represented by structural engineering parameters that associated with a plane extending along two perpendicular axes, such as material types, fabrication parameters, construction parameters, load parameters and so forth.

Adjustment system 110 can be implemented as one or more algorithms operating on a processor that cause the processor to adjust one or more predetermined elements. In one example embodiment, adjustment system 110 can generate one or more user controls that allow a user to select elements that require adjustment and to cause the adjustments to be automatically performed.

Continuity system 112 can be implemented as one or more algorithms operating on a processor that cause the processor to identify design elements that lack continuity. In one example embodiment, the design elements can be engineering design elements that are generated as a function of architectural design elements, and which can lack continuity with other engineering design elements, such as for reasons relating to the materials that the engineering design element is fabricated from, design constraints such as load bearing capacity or weight that are associated with an engineering design element or other suitable constraints.

User control interfaces 114A through 114N can be implemented as one or more algorithms operating on a processor that cause the processor to generate one or more user controls to allow a user to interact with the systems and functions of architectural building model conversion apparatus 102. In one example embodiment, user control interfaces 114A through 114N can be used to provide access to an associated user with a user account, user credentials and other access control restrictions, such as to limit the models or model sections that a user is allowed to access, to limit the conversion processes that a user is allowed to implement or for other suitable purposes.

FIG. 2 is a diagram of a system 200 for providing adjustments to a structural analytical model, in accordance with an example embodiment of the present disclosure. System 200 includes adjustment system 110 and selector system 202, cutback system 204, stretch system 206, offset system 208 and snap system 210, each of which can be implemented in hardware or a suitable combination of hardware and software.

Selector system 202 can be implemented as one or more algorithms operating on a processor that cause the processor to generate a selector tool for use in a graphical user interface. In one example embodiment, the selector tool can allow a user to select a function, to select one or more elements of an architectural model, to change the state of the selected elements based on the selected function, and to perform other suitable functions.

Cutback system 204 can be implemented as one or more algorithms operating on a processor that cause the processor to cut back one or more selected elements. In one example embodiment, an element can be cut back to connect to a second element that has been selected to be a target of the cutback for the selected cut-back element, so as to prevent the target cut-back element from being cut back to an undesired element. In this example embodiment, the cut-back element can have one or more parameters modified as a result of the cut-back, such as to have a new end point node, a new coordinate, a new material, a new construction process, a new time or other suitable parameters.

Stretch system 206 can be implemented as one or more algorithms operating on a processor that cause the processor to stretch one or more selected elements. In one example embodiment, an element can be stretched to connect to a second element that has been selected to be a target of the stretch for the selected cut-back element, so as to prevent the target stretched element from being stretched to an undesired element. In this example embodiment, the stretched element can have one or more parameters modified as a result of the stretch, such as to have a new end point node, a new coordinate, a new material, a new construction process, a new time or other suitable parameters.

Offset system 208 can be implemented as one or more algorithms operating on a processor that cause the processor to offset one or more selected elements. In one example embodiment, an element can be offset to connect to a second element that has been selected to be a target of the offset for the selected offset element, so as to prevent the target offset element from being offset to an undesired element. In this example embodiment, the offset element can have one or more parameters modified as a result of the offset, such as to have a new end point node, a new coordinate, a new material, a new construction process, a new time or other suitable parameters.

Snap system 210 can be implemented as one or more algorithms operating on a processor that cause the processor to snap one or more selected elements. In one example embodiment, an element can be snapped to connect to a second element that has been selected to be a target of the stretch for the selected snapped element, so as to prevent the target snapped element from being snapped to an undesired element. In this example embodiment, the snapped element can have one or more parameters modified as a result of the snap, such as to have a new end point node, a new coordinate, a new material, a new construction process, a new time or other suitable parameters.

In operation, system 300 allows a user to interact with an architectural building information model to generate structural engineer elements, such as to adjust the architectural elements to comply with the technical requirements of a structural engineering building information model. Because the parameters associated with elements in an architectural building information model are different from the parameters associated with elements in a structural engineering model and cannot be easily mapped, a tool-based system that allows a user to assist with the conversion allows selected elements and selected parameters to be changed.

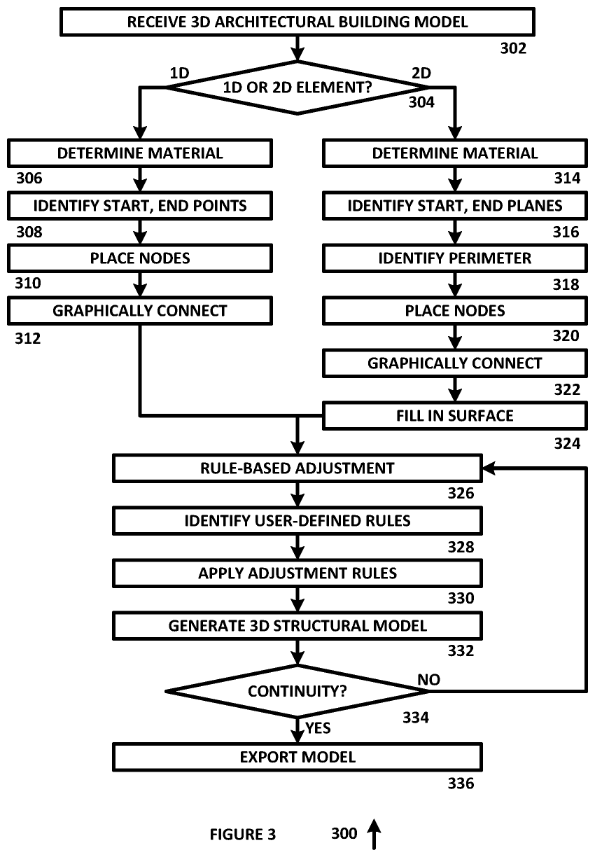

FIG. 3 is a diagram of an algorithm 300 for providing a structural analytical model apparatus, in accordance with an example embodiment of the present disclosure. Algorithm 300 can be implemented in hardware or a suitable combination of hardware and software.

Algorithm 300 begins at 302, where a 3D architectural building model is received. In one example embodiment, the 3D architectural building model can be received from a data storage device, can be generated in response to user inputs or can be received in other suitable manners. The algorithm then proceeds to 304.

At 304, an element is selected and it is determined whether the element is a one dimensional element or a two dimensional element. In one example embodiment, the element can be selected automatically, and steps 304 through 324 can be repeated until all elements have been processed. In another example embodiment, a graphical user interface tool can be used to allow a user to guide the element selection process, or other suitable mechanisms can also or alternatively be used. If it is determined that the selected element is a one dimensional element, the algorithm proceeds to 306, otherwise the algorithm proceeds to 314.

At 306, the materials associated with the element are determined. In one example embodiment, an architectural model can identify an element based on a desired material, a range of desired materials, a class of desired materials and so forth, and the material can be mapped to a structural engineering element material. The algorithm then proceeds to 308.

At 308, start and end points associated with element are identified. In one example embodiment, the start and end points in an architectural model can be determined based on coordinates or in other suitable manners. The algorithm then proceeds to 310.

At 310, nodes for the element are placed in a structural engineering model. In one example embodiment, nodes can be associated with other elements in the structural engineering model, such as where a beam or column has to connect to another structural engineering element at a predetermined location or node, in order to provide adequate structural support for the building. The algorithm then proceeds to 312.

At 312, the nodes of the element are graphically connected. In one example embodiment, a graphical representation of the structural engineering element can be generated to allow a user to review the structural engineering model and to identify areas where adjustments or modifications need to be made. The algorithm then proceeds to 326.

At 314, the materials associated with the element are determined. In one example embodiment, an architectural model can identify an element based on a desired material, a range of desired materials, a class of desired materials and so forth, and the material can be mapped to a structural engineering element material. The algorithm then proceeds to 316.

At 316, start and end planes associated with element are identified. In one example embodiment, the start and end planes in an architectural model can be determined based on coordinates or in other suitable manners. The algorithm then proceeds to 318.

At 318, the perimeter of the element is determined. In one example embodiment, a two dimensional structural engineering model element can have perimeter data associated with the element, such as to locate points at which the element will interface with other structural engineering model elements or for other suitable purposes. The algorithm then proceeds to 320.

At 320, nodes for the element are placed in a structural engineering model. In one example embodiment, nodes can be associated with other elements in the structural engineering model, such as where a wall or slab has to connect to another structural engineering element at predetermined locations or nodes, in order to provide adequate structural support for the building. The algorithm then proceeds to 322.

At 322, the nodes of the element are graphically connected. In one example embodiment, a graphical representation of the structural engineering element can be generated to allow a user to review the structural engineering model and to identify areas where adjustments or modifications need to be made. The algorithm then proceeds to 324.

At 324, the surface of the element are filled in. In one example embodiment, the surface of a two-dimensional structural engineering model element can have associated parameters that are needed to allow the element to be specified in the model, such as to identify quantities of materials associated with element, construction sequences and so forth. The algorithm then proceeds to 326.

At 326, a rule-based adjustment process is initiated. In one example embodiment, the rule-based adjustment process can be automatically initiated, can be initiated in response to selection of a user-control in a graphical user interface or can be initiated in other suitable manners. The algorithm then proceeds to 328.

At 328, one or more user-defined adjustment rules are identified. In one example embodiment, the user-defined adjustment rules can include an identification of architectural model elements that should be adjusted, an identification of related architectural model elements or structural engineering model elements that are to be included in the adjustment process, a type of adjustment that is to be performed such as a cut back, stretch, offset, snap or other suitable processes. The user-defined adjustment rules can be made in conjunction with graphical user interface tools and devices, as described and discussed further herein, which can be translated into one or more user-defined adjustment rules. For example, a target architectural model element and an associated structural engineering model element can be identified using a graphical user interface tool and a stretch command can be selected, and the algorithm can implement a stretch procedure to stretch one or dimensional parameters of the target architectural model element to be compatible with the associated structural engineering model element using predetermined rules associated with a stretch procedure. Likewise, other suitable processes as discussed within can also or alternatively be performed. The algorithm then proceeds to 330.

At 330, the user-identified adjustment rules are applied. In one example embodiment, one or more structural engineering model elements can be generated or modified in response to the application of the user-identified adjustment rules, or other suitable processes can also or alternatively be implemented. The algorithm then proceeds to 332.

At 332, a 3D structural model is generated. In one example embodiment, the 3D structural model can be generated and stored in a data memory device, a graphical user interface can be generated that displays the 3D structural model or other suitable processes can also or alternatively be used. The algorithm then proceeds to 334.

At 334, it is determined whether continuity exists for each of the 3D structural model elements. In one example embodiment, continuity can exist when each node of each element in a structural engineering model is connected to another node, when the nodes that are connected comply with predetermined technical, requirements or when other predetermined conditions are satisfied. If it is determined that continuity does not exist, the algorithm proceeds to 326, otherwise the algorithm proceeds to 330 where the model is exported.

In operation, algorithm 300 provides a structural analytical model apparatus that can be used to automatically convert architectural building elements into structural engineering elements. Although algorithm 300 is shown as a flow chart, a person of skill in the art will recognize that it can also or alternatively be implemented as a state diagram, a ladder chart, using object-oriented programming techniques or in other suitable manners.

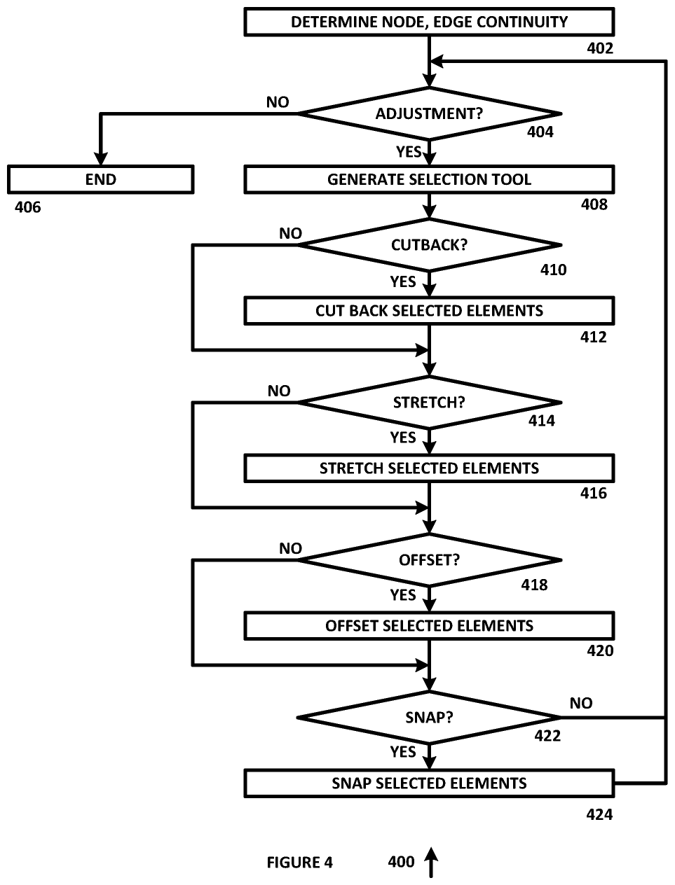

FIG. 4 is a diagram of an algorithm 400 for providing adjustments to a structural analytical model, in accordance with an example embodiment of the present disclosure. Algorithm 400 can be implemented in hardware or a suitable combination of hardware and software.

Algorithm 400 begins at 402, where it is determined whether node continuity exists, edge continuity exists or if other constraints have been satisfied. In one example embodiment, a graphical user interface can be generated that includes a predetermined indicator for structural engineering model elements that do not have node continuity, edge continuity or other predetermined parameters, such as to identify the affected elements, the affected nodes or edges or other suitable indicators. The algorithm then proceeds to 404.

At 404, it is determined whether any adjustments are required. In one example embodiment, an adjustment can be required if it is determined that node or edge continuity does not exist, or if other non-conformities are identified. If it is determined that no adjustments are required, the algorithm proceeds to 406 and ends. Otherwise, the algorithm then proceeds to 330.

At 408, a selection tool is generated in a user interface. In one example embodiment, the selection tool can include one or more of a cutback, stretch, offset or snap selection tool, such as in a graphic user interface that allows a user to select a tool and the elements that the tool is to be applied to. In another example embodiment, the applicable or recommended tool for a specific element can be indicated as part of the graphic user interface and can be included with a display of the element within the model, such as where the tools that are available to be used with the element are less than the total number of available tools. Other processes can also or alternatively be used. The algorithm then proceeds to 410.

At 410, it is determined whether a cutback tool has been selected. If a cutback tool as not been selected, the algorithm proceeds to 414, otherwise the algorithm proceeds to 412, where a cut back tool is applied to one or more selected elements. In one example embodiment, the cut back tool can modify a dimension or dimensions of an element by a user-selected amount, such as by allowing the user to indicate the cutback, by generating a proposed cutback for approval by the user or in other suitable manners. The algorithm then proceeds to 414.

At 414, it is determined whether a stretch tool has been selected. If a stretch tool as not been selected, the algorithm proceeds to 418, otherwise the algorithm proceeds to 416, where a stretch tool is applied to one or more selected elements. In one example embodiment, the stretch tool can modify a dimension or dimensions of an element by a user-selected amount, such as by allowing the user to indicate the amount that the element is to be stretched, by generating a proposed stretch for approval by the user or in other suitable manners. The algorithm then proceeds to 418.

At 418, it is determined whether an offset tool has been selected. If an offset tool as not been selected, the algorithm proceeds to 422, otherwise the algorithm proceeds to 420, where an offset tool is applied to one or more selected elements. In one example embodiment, the offset tool can modify a dimension or dimensions of an element by a user-selected amount, such as by allowing the user to indicate the offset, by generating a proposed offset for approval by the user or in other suitable manners. The algorithm then proceeds to 422.

At 422, it is determined whether a snap tool has been selected. If a snap tool as not been selected, the algorithm proceeds to 404, otherwise the algorithm proceeds to 422, where a snap tool is applied to one or more selected elements. In one example embodiment, the snap tool can modify a dimension or dimensions of an element by a user-selected amount, such as by allowing the user to indicate the target element that the selected element should be snapped to, by generating a proposed target element for approval by the user or in other suitable manners. The algorithm then proceeds to 404.

In operation, algorithm 400 provides a mechanism for making adjustments to a structural analytical model apparatus that can be used to automatically convert architectural building elements into structural engineering elements. Although algorithm 400 is shown as a flow chart, a person of skill in the art will recognize that it can also or alternatively be implemented as a state diagram, a ladder chart, using object-oriented programming techniques or in other suitable manners.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications, on one or more processors (where a processor includes one or more microcomputers or other suitable data processing units, memory devices, input-output devices, displays, data input devices such as a keyboard or a mouse, peripherals such as printers and speakers, associated drivers, control cards, power sources, network devices, docking station devices, or other suitable devices operating under control of software systems in conjunction with the processor or other devices), or other suitable software structures. In one exemplary embodiment, software can include one or more lines of code or other suitable software structures operating in a general purpose software application, such as an operating system, and one or more lines of code or other suitable software structures operating in a specific purpose software application. As used herein, the term “couple” and its cognate terms, such as “couples” and “coupled,” can include a physical connection (such as a copper conductor), a virtual connection (such as through randomly assigned memory locations of a data memory device), a logical connection (such as through logical gates of a semiconducting device), other suitable connections, or a suitable combination of such connections. The term “data” can refer to a suitable structure for using, conveying or storing data, such as a data field, a data buffer, a data message having the data value and sender/receiver address data, a control message having the data value and one or more operators that cause the receiving system or component to perform a function using the data, or other suitable hardware or software components for the electronic processing of data.

In general, a software system is a system that operates on a processor to perform predetermined functions in response to predetermined data fields. A software system is typically created as an algorithmic source code by a human programmer, and the source code algorithm is then compiled into a machine language algorithm with the source code algorithm functions, and linked to the specific input/output devices, dynamic link libraries and other specific hardware and software components of a processor, which converts the processor from a general purpose processor into a specific purpose processor. This well-known process for implementing an algorithm using a processor should require no explanation for one of even rudimentary skill in the art. For example, a system can be defined by the function it performs and the data fields that it performs the function on. As used herein, a NAME system, where NAME is typically the name of the general function that is performed by the system, refers to a software system that is configured to operate on a processor and to perform the disclosed function on the disclosed data fields. A system can receive one or more data inputs, such as data fields, user-entered data, control data in response to a user prompt or other suitable data, and can determine an action to take based on an algorithm, such as to proceed to a next algorithmic step if data is received, to repeat a prompt if data is not received, to perform a mathematical operation on two data fields, to sort or display data fields or to perform other suitable well-known algorithmic functions. Unless a specific algorithm is disclosed, then any suitable algorithm that would be known to one of skill in the art for performing the function using the associated data fields is contemplated as falling within the scope of the disclosure. For example, a message system that generates a message that includes a sender address field, a recipient address field and a message field would encompass software operating on a processor that can obtain the sender address field, recipient address field and message field from a suitable system or device of the processor, such as a buffer device or buffer system, can assemble the sender address field, recipient address field and message field into a suitable electronic message format (such as an electronic mail message, a TCP/IP message or any other suitable message format that has a sender address field, a recipient address field and message field), and can transmit the electronic message using electronic messaging systems and devices of the processor over a communications medium, such as a network. One of ordinary skill in the art would be able to provide the specific coding for a specific application based on the foregoing disclosure, which is intended to set forth exemplary embodiments of the present disclosure, and not to provide a tutorial for someone having less than ordinary skill in the art, such as someone who is unfamiliar with programming or processors in a suitable programming language. A specific algorithm for performing a function can be provided in a flow chart form or in other suitable formats, where the data fields and associated functions can be set forth in an exemplary order of operations, where the order can be rearranged as suitable and is not intended to be limiting unless explicitly stated to be limiting.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

What is claimed is:

1. A data processing system, comprising:
an architectural building model conversion apparatus operating on a first processor and implementing one or more algorithms that cause the processor to receive an architectural building model and to generate a structural engineering model; and
a plurality of user control interfaces, each operating on one of a plurality of second processors and implementing one or more algorithms that allow a user to control conversion of one or more architectural model elements to one or more corresponding structural engineering model elements.

2. The data processing system of claim 1 wherein the architectural building model conversion apparatus is configured to generate an integrated three-dimensional architectural and structural engineering building model.

3. The architectural building model conversion apparatus of claim 1 wherein the one or more converted architectural model elements can be exported directly into an integrated three-dimensional architectural and structural engineering building model.
